(19) United States
(12) Patent Application Publication
(10) Pub. No.: US 2013/0322150 A1
(43) Pub. Date: Dec. 5, 2013

(54) MEMORY DEVICE INCLUDING PROGRAMMABLE ANTIFUSE MEMORY CELL ARRAY

(71) Applicant: SAMSUNG ELECTRONICS CO., LTD., Suwon-si (KR)

(72) Inventors: Sung Hoon Kim, Seongnam-si (KR); Joung Yeal Kim, Yongin-si (KR); Se Il Oh, Incheon (KR)

(73) Assignee: SAMSUNG ELECTRONICS CO., LTD., Suwon-si (KR)

(21) Appl. No.: 13/803,336

(22) Filed: Mar. 14, 2013

(30) Foreign Application Priority Data
Jun. 1, 2012 (KR) 10-2012-0059368

(51) Int. Cl. G11C 17/08

(52) U.S. Cl. CPC G11C 17/08
USPC 365/104; 365/94

(57) ABSTRACT

A memory device includes a memory cell array, a column decoder, and a row decoder. The memory cell array includes a plurality of antifuse memory cells arranged in rows and columns, each of the antifuse memory cells connected to one of a plurality of word lines, one of a plurality of high-voltage lines, and one of a plurality of bit lines. The column decoder is arranged at a first side of the memory cell array and configured to select one bit line among the bit lines. The row decoder is arranged parallel to the column decoder in a first direction, and configured to select one word line among the word lines.

### CROSS-REFERENCE TO RELATED APPLICATIONS

This application claims priority under 35 U.S.C. §119(a) to Korean Patent Application No. 10-2012-0059368 filed on Jun. 1, 2012, the disclosure of which is hereby incorporated by reference in its entirety.

### BACKGROUND

The embodiments disclosed herein relate to a memory device, and more particularly, to a memory device with a layout enabling efficient chip area use.

In general, programmable memory is used in devices, such as micro controller units (MCUs), power integrated circuits (ICs), display driver ICs, and complementary metal oxide semiconductor (CMOS) image sensors, used as mobile parts or automobile parts. For such programmable memory, one-time programmable (OTP) memory, which occupies a small area, does not require an additional process, and is programmed by electrically shorting with a breakdown mechanism when a high voltage is applied to a thin gate oxide layer, is usually used.

Programmable memory devices such as OTP memory devices are usually programmed by breaking connections (using fuses) or creating connections (using antifuses) in a memory circuit. For instance, phase-change read-only memory (PROM) includes a fuse and/or an antifuse at a memory position or a bit and is programmed by triggering the fuse or the antifuse. Once programming is done, it is usually irreversible. Usually, programming is carried out after memory products are manufactured, taking a particular end use or application into account.

Fuse connection is implemented by resistive fuse elements that open or break at a certain amount of high current. Antifuse connection is implemented by a thin barrier formed of a non-conductive material (like silicon dioxide) between two conductive layers or terminals. When a certain high voltage is applied to the terminals, silicon dioxide or such non-conductive material becomes a short-circuit or becomes a low-resistance conductive passage between the two terminals.

Since design of peripheral circuits of programmable antifuse cell arrays is not simple, the area of a layout needs to be considered.

### SUMMARY

According to some embodiments, there is provided a memory device including a memory cell array, a column decoder, and a row decoder. The memory cell array includes a plurality of antifuse memory cells each connected to one of a plurality of word lines, one of a plurality of high-voltage lines, and one of a plurality of bit lines. The column decoder is arranged at a first side of the memory cell array, and configured to select one bit line among the bit lines. The row decoder is arranged parallel to the column decoder in a first direction and configured to select one word line among the word lines.

According to another embodiment, there is provided a memory device. The memory device includes a memory cell array, a control logic, a column decoder, a row decoder, and a sense amplifier. The memory cell array includes a plurality of antifuse memory cells each including a rupture transistor that is connected between a floating terminal and a first node and has a gate connected to a high-voltage line and an access transistor that is connected between the first node and a second node connected to a bit line and has a gate connected to a word line. The control logic is configured to output a bit line address, a word line address and a high-voltage line address of a first antifuse memory cell to be accessed. The column decoder is arranged at a first side of the memory cell array and configured to decode the bit line address and to select a bit line of the first antifuse memory cell. The row decoder is arranged parallel to the column decoder in a first direction and configured to decode the word line address and the high-voltage line address and to select a word line and a high-voltage line connected to the first antifuse memory cell. The sense amplifier is configured to sense and amplify data of the rupture transistor of the first antifuse memory cell.

According to other embodiment, there is a memory device including a memory cell array, a column decoder, and a row decoder. The memory cell array includes a plurality of antifuse memory cells arranged in rows and columns, each of the antifuse memory cells electrically connected to one of a plurality of word lines, one of a plurality of bit lines, and one of a plurality of high voltage lines. The column decoder is configured to select a bit line connected to an antifuse memory cell. The row decoder is configured to select a word line and a high voltage line, the word line and high voltage line connected to the antifuse memory cell. The word lines, bit lines, and high voltage lines are formed in a first metal layer and extend in a first direction.

### BRIEF DESCRIPTION OF THE DRAWINGS

The present disclosure will become more apparent by describing in detail exemplary embodiments thereof with reference to the attached drawings in which:

FIG. 1 is an exemplary overall block diagram of an antifuse memory device including an antifuse memory cell array according to some embodiments;

FIG. 2 is a circuit diagram of an antifuse memory cell illustrated in FIG. 1;

FIG. 3 is an exemplary circuit diagram of an antifuse memory cell array illustrated in FIG. 1 according to some embodiments;

FIG. 4 is an exemplary plan view of a couple of antifuse memory cells illustrated in FIG. 3 according to one embodiment;

FIG. 5 is an exemplary cross-sectional view of an antifuse memory cell, taken along the line X1-X1′ in FIG. 4 according to one embodiment;

FIG. 6 is an exemplary cross-sectional view of an antifuse memory cell, taken along the line X2-X2′ in FIG. 4 according to one embodiment;

FIG. 7 is an exemplary cross-sectional view of an example the antifuse memory cell illustrated in FIG. 2 according to one embodiment;

FIG. 8 is an exemplary overall block diagram of an antifuse device including an antifuse memory cell array according to some embodiments;

FIG. 9 is an exemplary block diagram of a memory device including an antifuse device according to some embodiments.

FIG. 10 is an exemplary overall block diagram of a system on chip (SoC) including an antifuse device according to some embodiments;

FIG. 11 is an exemplary diagram of a data processing system including a memory system according to some embodiments;

FIG. 12 is an exemplary block diagram of a data processing system including a memory system according to some embodiments;

FIG. 13 is an exemplary block diagram of a data processing system including a plurality of memory devices according to some embodiments;

FIG. 14 is an exemplary block diagram of a data storage system including a plurality of memory modules according to some embodiments;

FIG. 15 is an exemplary block diagram of a module including a plurality of memory devices according to some embodiments; and

FIG. 16 is an exemplary schematic conceptual diagram of a multi-chip package including a plurality of semiconductor devices according to some embodiments.

### DETAILED DESCRIPTION OF THE EMBODIMENTS

Variable example embodiments now will be described more fully hereinafter with reference to the accompanying drawings, in which embodiments of the disclosure are shown. The present disclosure may, however, be embodied in many alternate forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.). As used herein, the term “and/or” includes any and all combinations of one or more of the associated listed items and may be abbreviated as “/”.

It will be understood that, although the terms first, second, etc. may be used herein to describe various elements, components, regions, layers and/or sections, these elements, components, regions, layers and/or sections, should not be limited by these terms. Unless the context indicates otherwise, these terms are only used to distinguish one element, component, region, layer or section from another element, component, region, layer or section. For example, a first element, component, region, layer or section discussed below could be termed a second element, component, region, layer or section without departing from the teachings of the present disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms such as “comprises,” “comprising,” “includes,” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein are to be interpreted as is customary in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

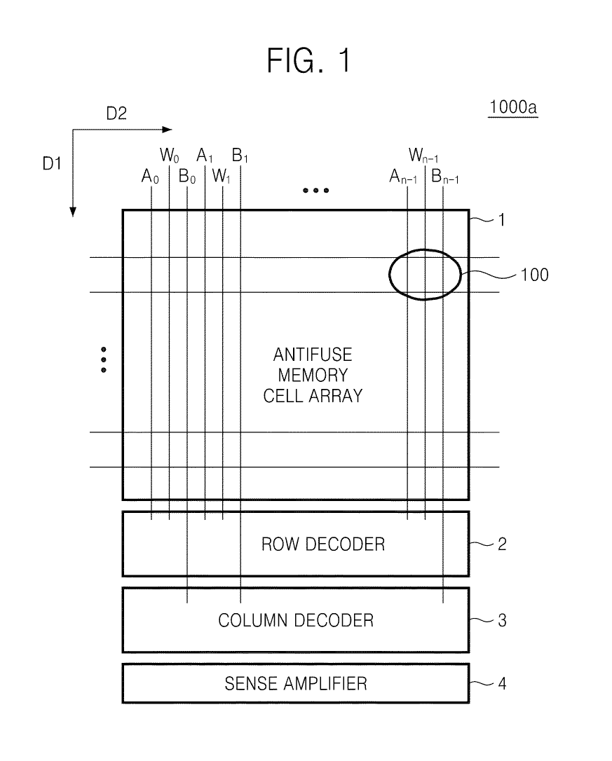

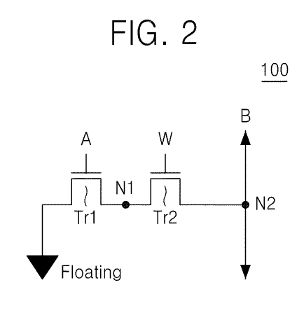

FIG. 1 is an exemplary overall block diagram of an antifuse device 1000a including an antifuse memory cell array 1 according to some embodiments. FIG. 2 is a circuit diagram of an antifuse memory cell 100 illustrated in FIG. 1 according to one embodiment.

Referring to FIGS. 1 and 2, the antifuse device 1000a includes the antifuse memory cell array 1, a row decoder 2, a column decoder 3, and a sense amplifier 4.

The antifuse memory cell array 1 includes a plurality of antifuse memory cells 100. Each of the antifuse memory cells 100 includes two transistors. A first transistor (or a rupture transistor) Tr1 has a gate connected to a high-voltage line A and a source and a drain respectively connected to a first node N1 and a floating terminal. A second transistor (or an access transistor) Tr2 has a gate connected to a word line W and a source and a drain respectively connected to a second node N2 and the first node N1. The second node N2 is connected to a first bit line B.

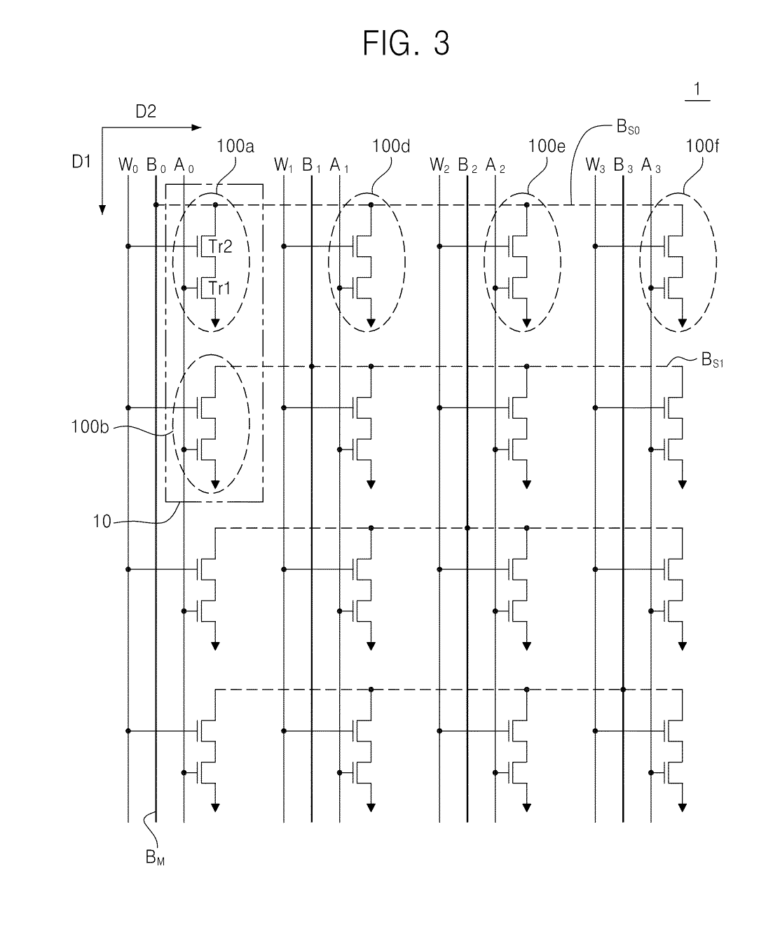

The word line W, the high-voltage line A, and the first bit line B may be extended in a first direction D1 and arranged in parallel separated from one another. The layout of the lines W, A, and B will be described in detail later with reference to FIG. 3.

The row decoder 2 is arranged parallel to the column decoder 3 in a second direction D2, for example, perpendicular to the first direction D1. The row decoder 2 overlaps the column decoder 3 in the first direction D1. The row decoder 2 selects the word line W based on a row of a first antifuse memory cell to be accessed in the antifuse memory cell array 1, i.e., a decoded word line address. Although the row decoder 2 is positioned between the antifuse memory cell array 1 and the column decoder 3 in the embodiments illustrated in FIG. 1, the disclosure is not restricted to the current embodiments. In one embodiment, the row decoder 2 may be positioned between the column decoder 3 and the sense amplifier 4 or may be positioned on another side of the antifuse memory cell array 1 opposite to the column decoder 3, i.e., above the antifuse memory cell array 1 in FIG. 1. The column decoder 3 selects the first bit line B based on a column of the first antifuse memory cell to be accessed in the antifuse memory cell array 1, i.e., a decoded bit line address. For example, the column decoder 3 may include a plurality of column select transistors (not shown) and generate a plurality of bit line selection signals to select one of the column select transistors. Each of the column select transistors may be connected to a bit line and the bit line may be selected in response to one of the bit line selection signals. The sense amplifier 4 senses and amplifies data of the first antifuse memory cell that has been accessed.

FIG. 3 is an exemplary circuit diagram of the antifuse memory cell array 1 illustrated in FIG. 1 according to some embodiments. The antifuse memory cell array 1 illustrated in FIG. 3 is a 4×4 memory cell array, but the disclosure is not restricted to the current embodiments. The antifuse memory cell array 1 may be implemented in different size, i.e., N×M where N and M are an integer.

Each memory cell 100 is connected to a word line W, a bit line B, and a high-voltage line A. The word line W and the bit line B are connected to the access transistor Tr2 to access a target cell. The high-voltage line A is connected to the gate of an antifuse cell, i.e., the rupture transistor Tr1 to apply a high voltage for programming the antifuse cell. For example, the high voltage may be higher than a voltage applied to the word line W and the bit line B and is a programming voltage for the rupture transistor Tr1. Since the rupture transistor Tr1 may have a thinner gate oxide than the access transistor Tr2, when the high voltage is applied to the rupture transistor Tr1, the gate oxide of the rupture transistor Tr1 is broken so that the rupture transistor Tr1 is programmed.

The word line W (W₀,W₁,W₂,W₃), the high-voltage line A (A₀,A₁,A₂,A₃) and the first bit line B (B₀,B₁,B₂,B₃) extend in the first direction D1 and arranged in parallel separated from one another. In addition, a second bit line B_{S} may extend in the second direction D2 in order to connect neighboring memory cells in a column. For instance, a second node N2 of the target cell 100a may be connected with a second node N2 of each of neighboring cells 100d, 100e, and 100f through the second bit line B_{S}. The antifuse memory cell array 1 may comprise a couple of antifuse memory cells 10, which includes first and second memory cells 100a and 100b. For example, the word line W, the high-voltage line A, and the first bit line B may be formed in the same layer (e.g., a first metal layer). The second bit line Bs may be formed in a second metal layer formed at a different level from the first metal layer.

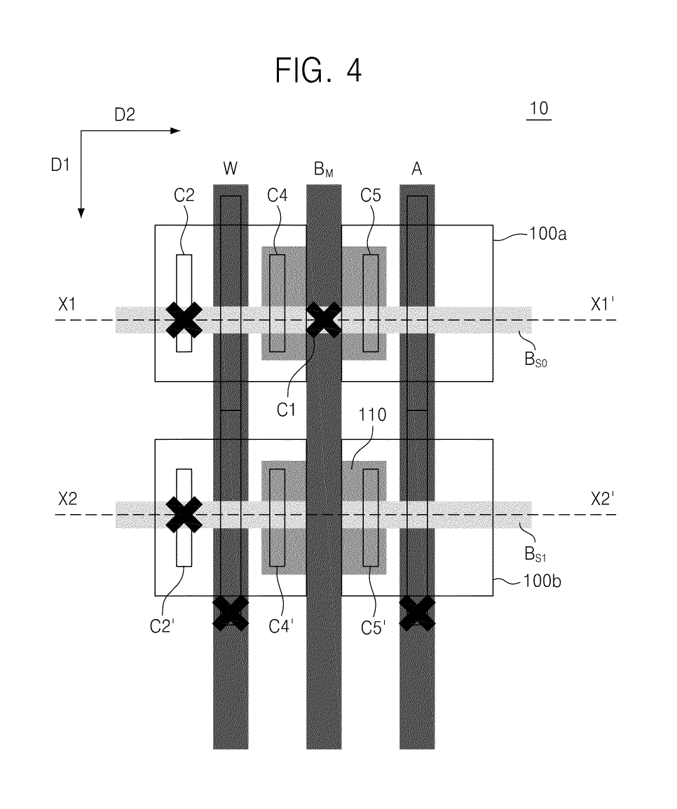

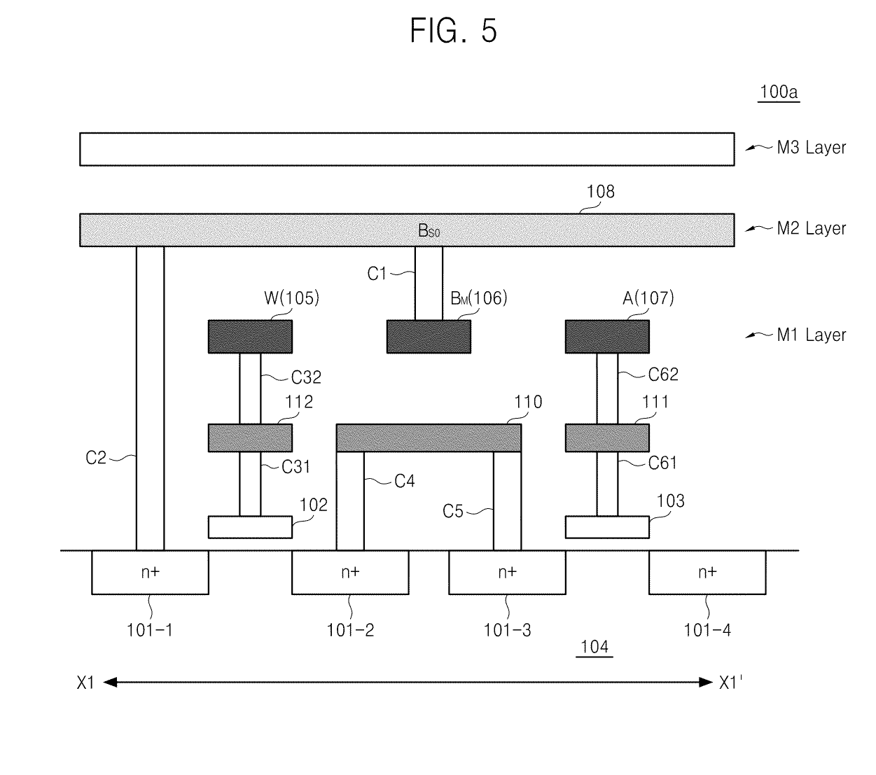

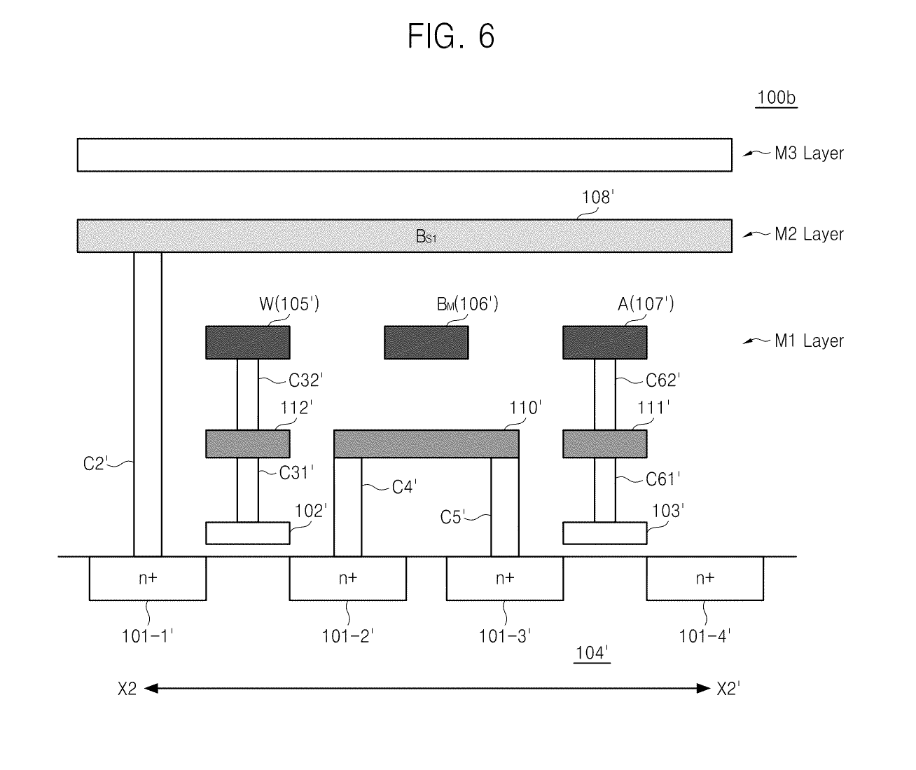

FIG. 4 is an exemplary plan view of a couple of antifuse memory cells 10 illustrated in FIG. 3 according to one embodiment. FIG. 5 is an exemplary cross-sectional view of an antifuse memory cell 100a, taken along the line X1-X1′ in FIG. 4 according to one embodiment. FIG. 6 is an exemplary cross-sectional view of an antifuse memory cell 100b, taken along the line X2-X2′ in FIG. 4 according to one embodiment. Referring to FIG. 4, a word line W, a first bit line B_{M}, a second bit line B_{S0}, and a high-voltage line A are connected to the first memory cell 100a. The first bit line B_{M} and the second bit line B_{S0} are formed in different metal layers, respectively, and connected to each other through a contact C1.

Referring to FIGS. 4 and 5, the first memory cell 100a includes a substrate 104, a plurality of source/drain (S/D) regions 101-1 through 101-4, a plurality of contacts C1 through C62, gates 102 and 103, bit line poly layers 110 through 112, first metal terminals 105, 106, and 107, and a second metal terminal 108. The substrate 104 includes the S/D regions 101-1 through 101-4.

The first memory cell 100a may include two N-type metal oxide semiconductor (NMOS) transistors, i.e., a rupture transistor Tr1 and an access transistor Tr2. The source of Tr1 and the drain of Tr2 may be combined. For example, the NMOS transistor Tr1 may be positioned within the substrate 104 or a P-well (not shown). The gate 103 is formed on a gate oxide. The bit line poly layer 110 connects the two S/D regions 101-2 and 101-3 in series.

A high voltage is applied to the gate 103 of the rupture transistor Tr1 through a high-voltage line A formed in the first metal layer M1, the contacts C62 and C61, and an intermediate bit line poly layer, so that a channel is formed in the substrate 104 below the gate 103. For example, the gate oxide of the rupture transistor Tr1 may be broken by applied high voltage to the gate 103.

A word line selection voltage is applied to the gate 102 of the access transistor Tr2 through a word line terminal 105 in the first metal layer M1, the contacts C32 and C31, and an intermediate bit line poly layer 112, so that a channel is formed in the substrate 104 below the gate 102.

A first bit line B_{M} connects to the second bit line B_{S0} through the contact C1. The second bit line B_{S0} connects to the S/D region 101-1 through the contact C2. The contact C2 may be formed through a first metal layer (not shown) to have a planarization during a manufacturing process for the antifuse device. The second bit line B_{S0} may be formed in the second metal layer M2.

The second bit line B_{S0} is illustrated as a part of the second metal layer M2 and may be disposed in a direction different than, for example, in a perpendicular direction to, the first bit line B_{M}, the word line W, and the high-voltage line A. For example, the first bit line B_{M}, the word line W, and the high-voltage line A in the first metal layer M1 may be disposed in a first direction D1, and the second bit line B_{S0} in the second metal layer M2 may be disposed in a second direction D2, that is perpendicular to the D1.

In one embodiment, a memory cell array including the first memory cell 100a may also include a third metal layer M3. The third metal layer M3 may include a power line connected to the antifuse device 1000a or to connection lines to peripheral circuits (e.g., a row decoder, a column decoder, a sense amplifier, etc.).

Referring to FIGS. 4 and 6, the second memory cell 100b includes a substrate 104′, a plurality of source/drain (S/D) regions 101-1′ through 101-4′, a plurality of contacts C2′ through C62′, gates 102′ and 103′, a bit line poly layer 110′, first metal terminals 105′, 106′, and 107′, and a second bit line B_{S1}. For convenience' sake in the description, differences between the second memory cell 100b and the first memory cell 100a illustrated in FIG. 5 will be mainly described.

In the second memory cell 100b, the first bit line B_{M} and the second bit line B_{S1} are not connected. Accordingly, even when a bit line selection signal is applied from the column decoder 3 to the first bit line B_{M}, the access transistor Tr2 of the second memory cell 100b is in an off state and does not sense the cell state of the rupture transistor Tr1.

In the current embodiments of the present disclosure, the row decoder 2 and the column decoder 3 are arranged in one direction in the antifuse device 1000a, and therefore, an antifuse device set may be formed in a rectangular shape. As a result, a chip area can be efficiently used.

In addition, a word line and a bit line are extended in one direction and arranged in parallel separated from each other. Accordingly, they have providing shield effect and enable uni-direction layout design.

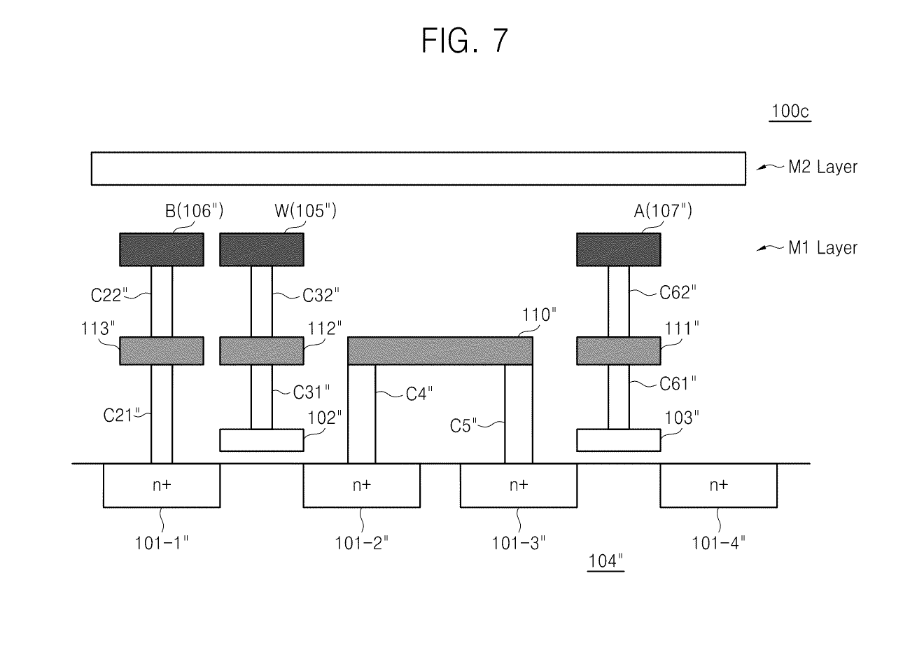

FIG. 7 is an exemplary cross-sectional view of an example of the antifuse memory cell 100 illustrated in FIG. 2 according to one embodiment. Referring to FIG. 7, a third memory cell 100c includes the substrate 104″, a plurality of source/drain (S/D) regions 101-1″ through 101-4″, a plurality of contacts C4″ through C62″, gates 102″ and 103″, bit line poly layers 110″ through 113″, and first metal terminals 105″, 106″, and 107″.

The operational principle of the third memory cell 100c is the same as that of the memory cells 100a and 100b illustrated in FIGS. 4 through 6. However, unlike the memory cells 100a and 100b illustrated in FIGS. 4 through 6, the third memory cell 100c may have a bit line B, a word line W, and a high-voltage line A all arranged in the first metal layer M1.

In one embodiment, a memory cell array including the third memory cell 100c may also include the second metal layer M2 may include a power line connected to the antifuse device 1000a or to connection lines to peripheral circuits (e.g., a row decoder, a column decoder, a sense amplifier, etc.).

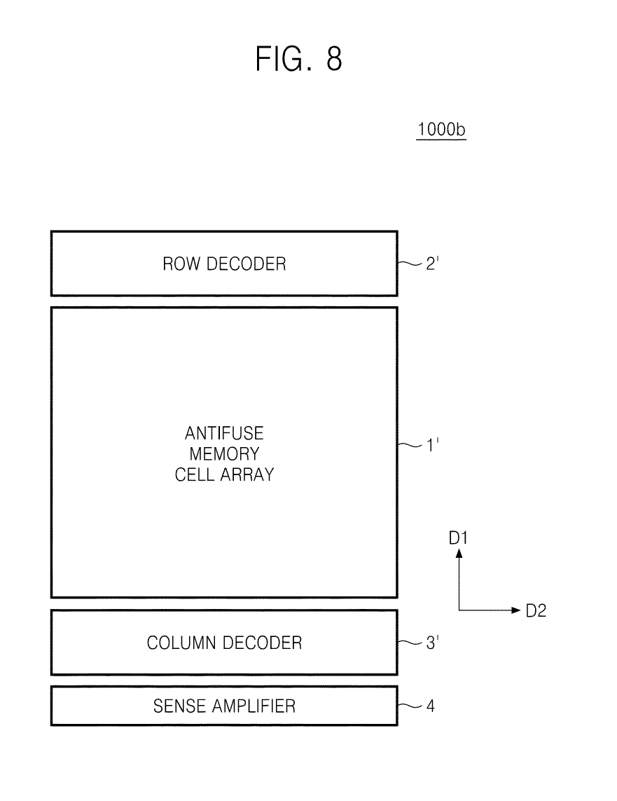

FIG. 8 is an exemplary overall block diagram of an antifuse device 1000b including an antifuse memory cell array 1′ according to some embodiments. Differences between the antifuse device 1000b illustrated in FIG. 8 and the antifuse device 1000a illustrated in FIG. 1 will be mainly described. A row decoder 2′ may be positioned at a side of the antifuse memory cell array 1′ opposite to a column decoder 3′. In other words, the row decoder 2′ and the column decoder 3′ may be positioned at opposite sides, respectively, of the antifuse memory cell array 1′.

Each of memory cells included in the antifuse memory cell array 1′ illustrated in FIG. 8 also may include two transistors, i.e., a rupture transistor Tr1 and an access transistor Tr2. Referring to FIGS. 2 and 8, a gate of the first transistor, i.e., the rupture transistor Tr1 is connected to the high-voltage line A and source and drain thereof are connected to the first node N1 and the floating terminal. A gate of the second transistor, i.e., the access transistor Tr2 is connected to the word line W and source and drain thereof are connected to the second node N2 and the first node N1. The second node N2 is connected to a first bit line B.

The word line W, the high-voltage line A, and the first bit line B may extend in a first direction D1 and arranged in parallel separated from each another.

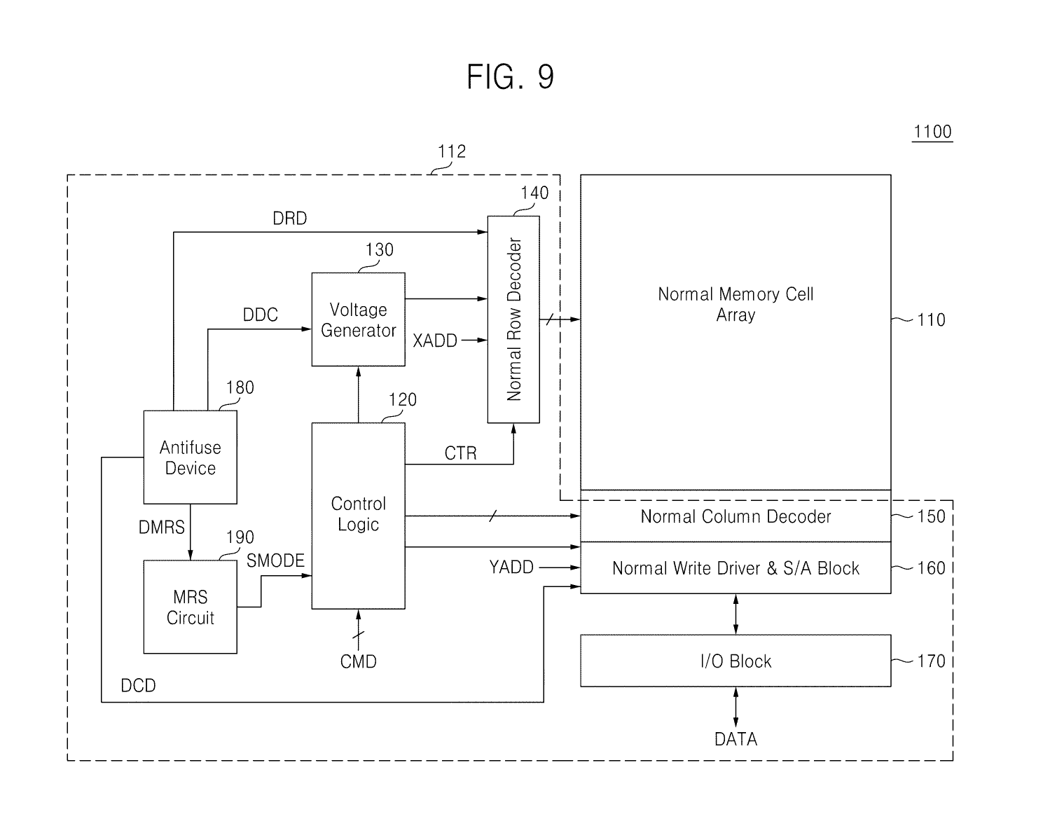

FIG. 9 is an exemplary block diagram of a memory device 1100 including an antifuse device 180 according to some embodiments. Referring to FIG. 9, the memory device 1100 may include a normal memory cell array 110 and a control circuit 112. The normal memory cell array 110 includes a plurality of normal memory cells and is electrically connected to a plurality of normal bit lines and a plurality of normal word lines.

The memory device 1100 may be implemented by a volatile or non-volatile memory device. The volatile memory device may include, for example, dynamic random access memory (DRAM), static RAM (SRAM), thyristor RAM (T-RAM), zero capacitor RAM (Z-RAM), or twin transistor RAM (TTRAM).

The non-volatile memory device may include, for example, electrically erasable programmable read-only memory (EEPROM), flash memory, magnetic random access memory (MRAM), spin-transfer torque MRAM, conductive bridging RAM (CBRAM), ferroelectric RAM (FeRAM), phase-change RAM (PRAM), resistive RAM (RRAM), nanotube RRAM, polymer RAM (PoRAM), nano floating gate memory (NFGM), holographic memory, molecular electronic memory device, or insulator resistance change memory.

The normal memory cell array 110 may include a plurality of normal memory cells storing data. The normal cell array 110 may be implemented in a two- or three-dimensional structure.

The control circuit 112 may access the normal memory cell array 110 to perform a data access operation, e.g., a read operation, according to a set of commands CMD, XADD, and YADD received from an external device, e.g., a memory controller (not shown). In one embodiment, the control circuit 112 controls the normal memory cell array 110 to perform a program operation (or a write operation) or an erase operation.

The control circuit 112 includes a control logic 120, a voltage generator 130, a normal row decoder 140, a normal column decoder 150, a normal write driver and sense amplifier (S/A) block 160, an input/output (I/O) block 170, the antifuse device 180, and a mode register set (MRS) circuit 190.

The control logic 120 may control the overall operation of the control circuit 112 in response to a command (e.g., CMD) included in a command set. The voltage generator 130 may generate a voltage used for the data access operation according to a control code generated by the control logic 120. Although the voltage generated by the voltage generator 130 is applied to the normal row decoder 140 in FIG. 9 for convenience' sake in the description, the disclosure is not restricted thereto.

The normal row decoder 140 may decode the normal row address XADD according to a control signal CTR received from the control logic 120. The normal column decoder 150 may decode the normal column address YADD under the control of the control logic 120.

The normal write driver and S/A block 160 may function as a sense amplifier that can sense and amplify a voltage level of each of a plurality of normal bit lines included in the normal memory cell array 110 according to the control of the control logic 120 when the memory device 1100 performs the read operation. The normal write driver and S/A block 160 may function as a write driver that can drive each of the normal bit lines included in the normal memory cell array 110 according to the control of the control logic 120 when the memory device 1100 performs the write operation.

The I/O block 170 may transmit data received from an external device to the normal column decoder 150 through the normal write driver and S/A block 160 and transmit data output from the normal column decoder 150 to a device outside the memory device 1100, e.g., the memory controller (not shown). The antifuse device 180 according to certain embodiments may store trimming data DDC related to the trimming a level of voltage or a level of current used for the operation of the memory device 1100.

The trimming data DDC may include information about the level of voltage or current used when the voltage generator 130 trims a voltage or a current.

The antifuse device 180 may store defective cell address data related to defective cells in the normal memory cell array 110. For instance, the antifuse device 180 may store row data DRD including a normal row address of the defective cells or column data DCD including a normal column address of the defective cells.

The fuse device 180 may store MRS data DMRS related to the setting of the MRS circuit 190. The MRS data DMRS may include information, e.g., an operating frequency and/or a direct current (DC) voltage level, used for the operation of the memory device 1100 according to the operation mode of the memory device 1100.

The trimming data DDC read from the antifuse device 180 may be transmitted to the voltage generator 130. The voltage generator 130 may generate a voltage based on the trimming data DDC. The row data DRD read from the antifuse device 180 may be transmitted to the normal row decoder 140. The normal row decoder 140 may decode the normal row address XADD based on the row data DRD.

When the normal row address XADD is the same as the normal row address of a defective normal cell, the normal row decoder 140 may remap the normal row address XADD to a normal row address of a redundancy cell corresponding to the defective normal cell.

The column data DCD read from the antifuse device 180 may be transmitted to the normal column decoder 150. The normal column decoder 150 may decode the normal column address YADD based on the column data DCD.

When the normal column address YADD is the same as the normal column address of a defective normal cell, the normal column decoder 150 may remap the normal column address YADD to a normal column address of a redundancy cell corresponding to the defective normal cell.

The MRS data DMRS read from the antifuse device 180 may be transmitted to the MRS circuit 190.

The MRS circuit 190 may include a mode register (not shown). The MRS circuit 190 may set a mode register (not shown) included in the MRS circuit 190 based on the MRS data DMRS read from the antifuse device 180. The MRS circuit 190 may send a mode signal SMODE to the control logic 120. The control logic 120 may control the overall operation of the memory device 1100 based on the mode signal SMODE.

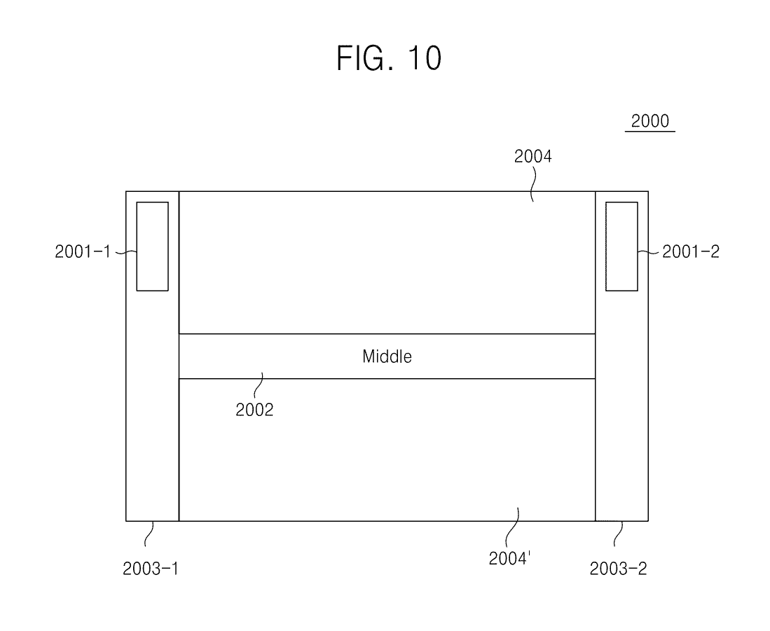

FIG. 10 is an exemplary overall block diagram of a system on chip (SoC) 2000 including the antifuse device disclosed herein according to some embodiments. Referring to FIG. 10, the SoC 2000 may have a plurality of pads in a middle region 2002. The SoC 2000 includes normal memory cell array 2004 and 2004′, antifuse devices 2001-1 and 2001-2a, and edge regions 2003-1 and 2003-2. The antifuse devices 2001-1 and 2001-2 may be the antifuse device disclosed herein, respectively.

When the SoC 2000 includes antifuse devices 2001-1 and 2001-2, the first antifuse device 2001-1 and the second antifuse device 2001-2 may be arranged in one direction to be parallel with and separated from each other, and located in edge regions of the SoC 2000. As compared to when the first antifuse device 2001-1 and the second antifuse device 2001-2 are respectively arranged in the middle region 2002, when the first antifuse device 2001-1 and the second antifuse device 2001-2 arranged in the edge regions 2003-1 and 2003-2, respectively, the total area of the SoC 2000 may be reduced.

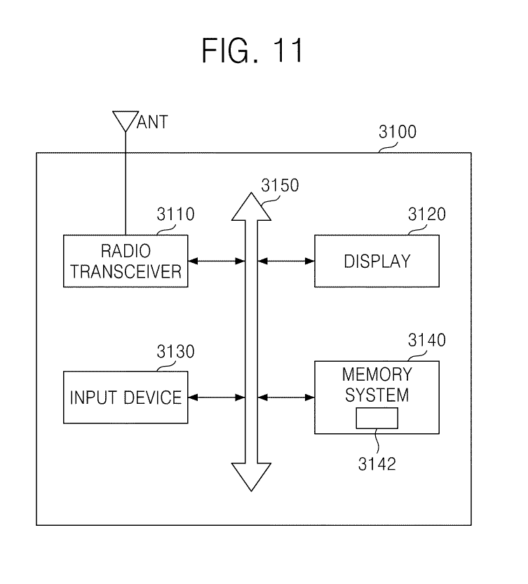

FIG. 11 is an exemplary diagram of a data processing system 3100 including a memory system 3140 according to some embodiments. Referring to FIG.11, the data processing system 3100 may be implemented as a cellular phone, a smart phone, a PDA (personal digital assistant), or wireless communications devices. The data processing system 3100 includes a memory system 3140. The memory system 3140 includes a memory device 3142 and a memory controller (not shown) controlling the operations of the memory device 3142. The memory device 3142 may include the antifuse device disclosed herein. The memory controller may control data (DATA) access operation of the memory device 3142, for example, the program operation, erase operation, or read operation, under the control of a processor. The page data programmed in the memory device 3142 may be displayed through the display 3120 under the control of the processor and the memory controller.

A radio transceiver 3110 may transmit or receive radio signals through an antenna ANT. For example, the radio transceiver 3110 may change the wireless signal received through the antenna ANT as a signal that can be handled by the processor. A processor (not shown) may process the signals output from the radio transceiver 3110 and transmit the processed signals to the memory system 3140 or a display 3120. The radio transceiver 3110 may also convert signals output from the processor into radio signals and output the radio signals to an external device through the antenna ANT.

An input device 3130 enables control signals for controlling the operation of the processor or data to be processed by the processor to be input to the data processing system 3100. The input device 3130 may be implemented as a pointing device such as touch pad and computer mouse, keypad, or keyboard. The processor may control the operation of the display 3120 to display data output from the memory system 3140, data output from the radio transceiver 3110, or data output from the input device 3130. The memory controller for controlling the memory device 3142 may be piled on the memory device 3142 in a stack structure.

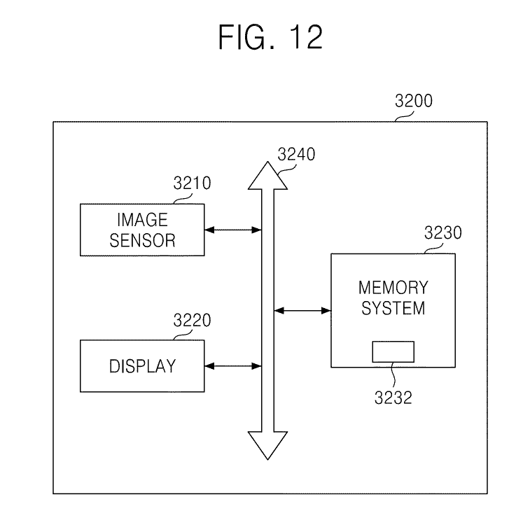

FIG. 12 is an exemplary block diagram of a data processing system 3200 including a memory system 3230 according to some embodiments. Referring FIG. 12, the data processing system 3200 may be implemented as an image processing apparatus like a digital camera, a cellular phone equipped with a digital camera, a smart phone equipped with a digital camera, or a tablet PC equipped with a digital camera.

The data processing system 3200 includes an image sensor 3210, a display 3220, and a memory system 3230. The memory system 3230 may include a memory device 3232 and a memory controller (not shown) controlling the data processing operations of the memory device 3232. The memory device 3232 may include the antifuse device disclosed herein. The image sensor 3210 included in the data processing system 3200 converts optical images into digital signals and outputs the digital signals to the memory system 3230. The digital signals may be displayed through the display 3230 or stored in the memory device 3232 through the memory controller according to processing of the memory system 3230.

Data stored in the memory device 3232 may be displayed through the display 3230. The memory controller, which may control the operations of the memory device 3232, may be implemented as a part of the processor or as a separate chip.

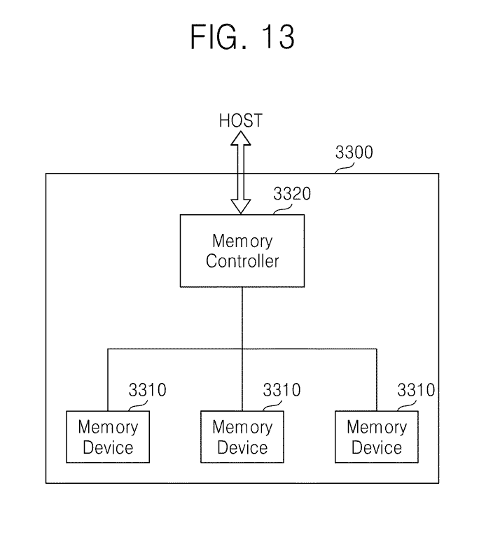

FIG. 13 is an exemplary block diagram of a data processing system 3300 including a plurality of memory devices 3310 according to some embodiments. Referring FIG. 13, the data processing system 3300 may be implemented as a data storage system like a solid state drive (SSD).

The data processing system 3300 includes a plurality of memory devices 3310 and a memory controller 3320 controlling the data processing operations of each of the plurality of the memory devices 3310. Each of the memory devices 3310 may include the antifuse device disclosed herein. The data processing system 3300 may be embodied as a memory module.

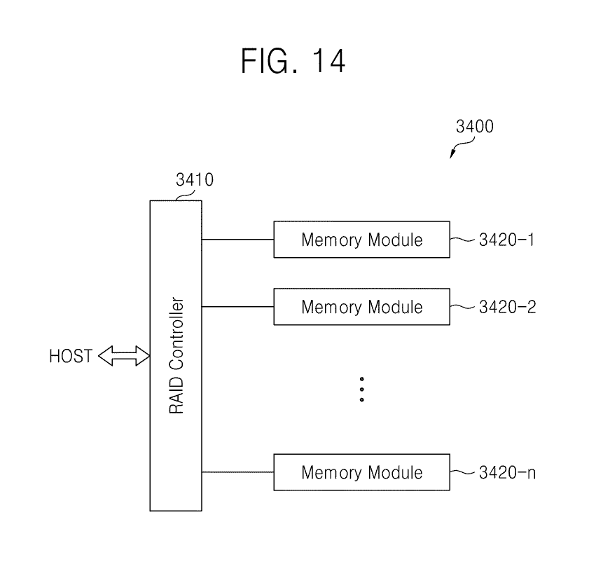

FIG. 14 is an exemplary block diagram of a data storage system 3400 including a plurality of memory modules according to some embodiments. Referring to FIG. 14, the data storage system 3400 may be implemented as a redundant array of independent disks (RAID) system. The data storage system 3400 includes a RAID controller 3410 and a plurality of memory modules 3420-1 through 3420-n where “n” is a natural number.

Each of the memory modules 3420-1 through 3420-n may be the data processing system 3300 illustrated in FIG. 12. The memory modules 3420-1 through 3420-n may form a RAID array. The data storage system 3400 may be a PC or an SSD.

During a program operation, the RAID controller 3410 may transmit program data output from a host to at least one of the memory modules 3420-1 through 3420-n according to a RAID level in response to a program command received from the host. During a read operation, the RAID controller 3410 may transmit to the host data read from at least one of the memory modules 3420-1 through 3420-n in response to a read command received from the host.

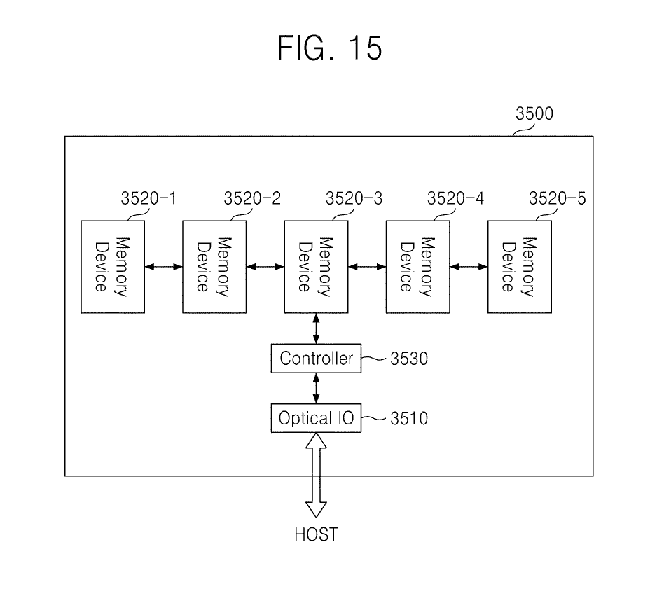

FIG. 15 is a block diagram of a module 3500 including a plurality of memory devices according to some embodiments. Referring to FIG. 15, the module 3500 may include a plurality of memory devices 3520-1 through 3520-5, a memory controller 3530, and an optical interface 3510 for interfacing data input/output of each of the plurality of memory devices 3520-1 through 3520-5. Each of the memory devices 3520-1 through 3520-5 may include the antifuse device disclosed herein.

The optical interface 3510 may include an input/output control device for controlling data input/output of each of the plurality of memory devices 3520-1 through 3520-5, and a signal converting device for converting data input or output from the memory device to optical signal.

The optical interface 3510 provides data exchange between each of the plurality of memory devices 3520-1 through 3520-5 and a host using optical communication. The optical interface 3510 may transmit or receive data using an optical fiber or a waveguide.

The exchanged data may be suitable for transceiving high speed signal like serial ATA (SATA) standard signal. The data may be transmitted and received using Wavelength Division Multiplex.

The memory controller 3530, which may control the operations of the memory devices 3520-1 through 3520-5, may be implemented as a part of the memory devices 3520-1 through 3520-5 or may be piled on or between the memory devices 3520-1 through 3520-2, in a stack structure.

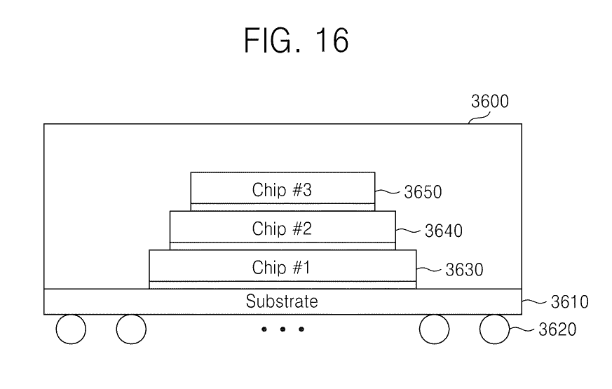

FIG. 16 is an exemplary schematic conceptual diagram of a multi-chip package 3600 including a plurality of semiconductor devices according to some embodiments. Referring to FIG. 16, the multi-chip package 3600 may include a plurality of semiconductor devices, i.e., first through third chips 3630, 3640, and 3650 which are sequentially stacked on a package substrate 3610. Each of the semiconductor devices 3630 through 3650 may be a memory controller or a memory device including the antifuse device disclosed herein. A through-substrate via (TSV, e.g., through-silicon via) (not shown), a bonding wire (not shown), a bump (not shown), or a solder ball 3620 may be used to electrically connect the semiconductor devices 3630 through 3650 with one other.

As described above, according to some embodiments, a row decoder and a column decoder are arranged in one direction in an antifuse device, thereby enabling a chip area to be used efficiently.

In addition, a word line and a bit line are extended in one direction and arranged in parallel separated from each other, thereby having different operation timings. As a result, a shield effect may be provided and uni-direction layout design is realized.

While the disclosure has been particularly shown and described with reference to exemplary embodiments thereof, it will be understood by those of ordinary skill in the art that various changes in forms and details may be made therein without departing from the spirit and scope of the present disclosure as defined by the following claims.

What is claimed is:

1. A memory device comprising:
a memory cell array comprising a plurality of antifuse memory cells arranged in rows and columns, each of the antifuse memory cells connected to one of a plurality of word lines, one of a plurality of high-voltage lines, and one of a plurality of bit lines;
a column decoder arranged at a first side of the memory cell array and configured to select one bit line among the bit lines; and
a row decoder arranged parallel to the column decoder in a first direction and configured to select one word line among the word lines.

2. The memory device of claim 1, wherein each of the antifuse memory cells comprises:
a first transistor that is connected between a floating terminal and a first node and has a gate connected to one of the high-voltage lines; and
a second transistor that is connected between the first node and one of the bit lines and has a gate connected to one of the word lines, and
wherein the high-voltage lines, the bit lines, and the word lines are formed in a first metal layer.

3. The memory device of claim 2, further comprising:
a power line configured to supply a power voltage to the row decoder or the column decoder of the memory device,
wherein the power line is formed in a second metal layer formed at a different level from the first metal layer.

4. The memory device of claim 2, wherein the bit lines are further formed in a second metal layer formed at a different level from the first metal layer.

5. The memory device of claim 4, further comprising:
a power line configured to supply a power voltage to the row decoder or the column decoder of the memory device,
wherein the power line is formed in a third metal layer formed at a different level from the second metal layer.

6. The memory device of claim 1, wherein the word lines, the bit lines, and the high-voltage lines extend in a second direction perpendicular to the first direction.

7. The memory device of claim 6, wherein the bit lines further extend in the first direction.

8. The memory device of claim 1, wherein the row decoder is arranged at a second side of the memory cell array opposite to the first side and the memory cell array is located between the column decoder and the row decoder.

9. The memory device of claim 1, wherein the row decoder is arranged at the first side of the memory cell array and is located between the memory cell array and the column decoder.

10. A memory device comprising:
a memory cell array comprising a plurality of antifuse memory cells each comprising a rupture transistor that is connected between a floating terminal and a first node and has a gate connected to a high-voltage line and an access transistor that is connected between the first node and a second node connected to a bit line and has a gate connected to a word line;
a control logic configured to output a bit line address, a word line address and a high-voltage line address of a first antifuse memory cell to be accessed;
a column decoder arranged at a first side of the memory cell array and configured to decode the bit line address and to select a bit line of the first antifuse memory cell;
a row decoder arranged parallel to the column decoder in a first direction and configured to decode the word line address and the high-voltage line address, and to select a word line and a high-voltage line connected to the first antifuse memory cell; and
a sense amplifier configured to sense and amplify data of the rupture transistor of the first antifuse memory cell.

11. The memory device of claim 10, wherein the word line, the bit line, and the high-voltage line extend in a first direction.

12. The memory device of claim 11, further comprising:
a second metal layer connected to the bit line, the second metal layer extending in a second direction perpendicular to the first direction.

13. A memory device comprising:
a memory cell array including a plurality of antifuse memory cells arranged in rows and columns, each of the antifuse memory cells electrically connected to one of a plurality of word lines, one of a plurality of bit lines, and one of a plurality of high voltage lines;
a column decoder configured to select a bit line connected to an antifuse memory cell; and
a row decoder configured to select a word line and a high voltage line, the word line and high voltage line connected to the antifuse memory cell,
wherein the word lines, bit lines, and high voltage lines are formed in a first metal layer and extend in a first direction.

14. The memory device of claim 13, wherein for each antifuse memory cell electrically connected to the word line, the bit line, and the high voltage line, the word line is located between the bit line and the high voltage line.

15. The memory device of claim 13, wherein the column decoder is arranged at a first side of the memory cell array and the row decoder is arranged to overlap with the column decoder in a first direction and is parallel to the column decoder in a second direction perpendicular to the first direction.

16. The memory device of claim 15, wherein the row decoder is arranged at the first side and is located between the memory cell array and the column decoder.

17. The memory device of claim 15, wherein the row decoder is arranged at a second side of the memory cell array opposite to the first side and the memory cell array is located between the row decoder and the column decoder.

18. The memory device of claim 13, wherein each of the antifuse memory cells comprises:
a first transistor that is connected between a floating terminal and a first node and has a gate connected to one of the high-voltage lines; and
a second transistor that is connected between the first node and one of the bit lines and has a gate connected to one of the word lines.

19. The memory device of claim 13, wherein the bit lines are further formed in a second metal layer formed at a different level from the first metal layer and extend in a second direction perpendicular to the first direction.

20. The memory device of claim 13, further comprising:
a normal memory cell array including a plurality of normal memory cells arranged in rows and columns; and
a control circuit configured to control an operation of the normal memory cell array.
